(19) United States
(12) Patent Application Publication
(10) Pub. No.: US 2008/0238786 A1
(43) Pub. Date: Oct. 2, 2008

(54) APPARATUS FOR MAXIMIZING SIGNAL STRENGTH IN WIRELESS DEVICES

(75) Inventors: Lawrence E. Bakst, Sunnyvale, CA (US); Bryan Grziwok, Oakland, CA (US)

Correspondence Address: PELCO, 3500 PELCO WAY, CLOVIA, CA, 93612, US

(73) Assignee: PELCO, INC., Clovis, CA (US)

(21) Appl. No.: 12/055,480

(22) Filed: Mar. 26, 2008

Related U.S. Application Data
(60) Provisional application No. 60/920,312, filed on Mar. 26, 2007.

(51) Int. Cl. H01Q 1/24; G01R 29/08

(52) U.S. Cl. 343/702; 343/703

(57) ABSTRACT

A device for performing one of the functions from the group of functions of wireless transmission of a signal and wireless reception of a signal comprising a housing having a cavity on the outside surface of the housing and an antenna assembly comprising an antenna mounted on a member, the member having a ball at one end that mates with the cavity, the member having a plate having an aperture sized so that it can be moved along the member and attached to the housing so that the antenna can be moved in three dimensions and then fixedly secured in the cavity by the plate.

### CROSS-REFERENCE TO RELATED APPLICATION

This application is related to and claims the benefit of U.S. Provisional Patent Application Ser. No. 60/920,312, filed Mar. 26, 2007, entitled SYSTEM FOR ANTENNA ALIGNMENT USING ARTICULATED MOUNT WITH THREE DEGREES OF FREEDOM, the entirety of which is incorporated herein by reference.

### STATEMENT REGARDING FEDERALLY SPONSORED RESEARCH OR DEVELOPMENT

N/A

### BACKGROUND OF THE INVENTION

This invention relates generally to surveillance systems and, in particular, to a method and apparatus for dynamically controlling a video surveillance system.

Today's complex video security systems have started utilizing wireless technology to transmit the video images captured by surveillance cameras. For example, wireless encoders encode the signals generated by video cameras into MPEG streams and transmit them to another transceiver in the video surveillance network. The environment in which security cameras are employed often presents a significant problem for mounting wireless devices in a location that allows good transmission strength between the wireless devices. Moreover, the fact that many installations require an installer to mount the wireless device while standing on a ladder makes the installation even more difficult. Accordingly, there has arisen a need in the industry for a wireless device that maximizes the signal strength between wireless devices in a video surveillance system.

### SUMMARY OF THE INVENTION

In accordance with the present invention there is provided a device for performing one of the functions from the group of functions of wireless transmission of a signal and wireless reception of a signal. The device comprises a housing having a cavity on the outside surface of the housing and an antenna assembly. The antenna assembly comprises an antenna mounted on a member, and the member has a ball at one end that mates with the cavity. The member has a plate that has an aperture sized so that it can be moved along the member and attached to the housing so that the antenna can be moved in three dimensions and then fixedly secured in the cavity by the plate.

The present invention provides a wireless device that allows an antenna alignment that has three degrees of freedom to achieve optimal alignment and hence signal strength between wireless devices in a surveillance system. The antenna can be mounted to the wireless device before the device is installed, but still allow movement for alignment before the antenna is locked in final position. In addition, the present invention provides an indication of the signal strength so that an installer can move the antenna and observe the signal strength to maximize the signal strength. The combination of an antenna that has three degrees of freedom and a signal strength indicator provides an installer with an effective and efficient means of installation even when the installation requires that the installer use a ladder and when the remote antenna is distant and/or obscured such that it is not visible with conventional sighting equipment.

Other advantages and applications of the present invention will be made apparent by the following detailed description of the preferred embodiment of the invention.

### BRIEF DESCRIPTION OF THE SEVERAL VIEWS OF THE DRAWINGS

FIG. 1 is a front perspective view of one embodiment of the present invention.

FIG. 2 is a front perspective view of one embodiment of the antenna assembly of the present invention.

FIG. 3 is a back perspective view of one embodiment of the antenna assembly of the present invention.

FIG. 4 is a bottom view of one embodiment of the antenna assembly of the present invention.

FIG. 5 is a bottom view of one embodiment of a housing utilizing the present invention.

FIG. 6 is a back view of one embodiment of the present invention.

FIG. 7 is a partial front perspective view of one embodiment of the present invention.

FIG. 8 is a block diagram illustrating one embodiment of the present invention.

### DETAILED DESCRIPTION OF THE INVENTION

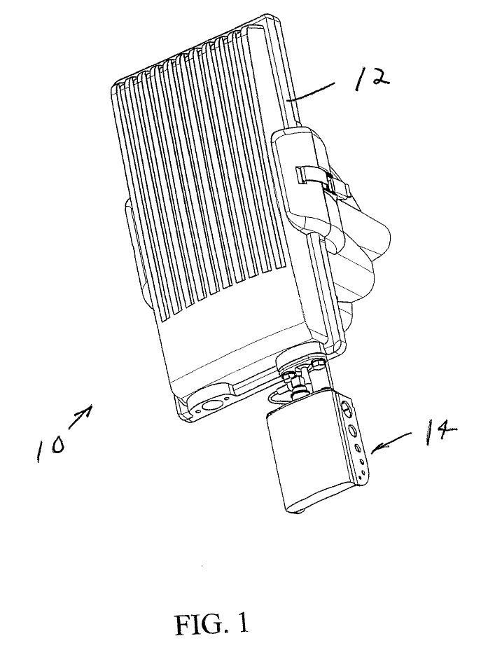

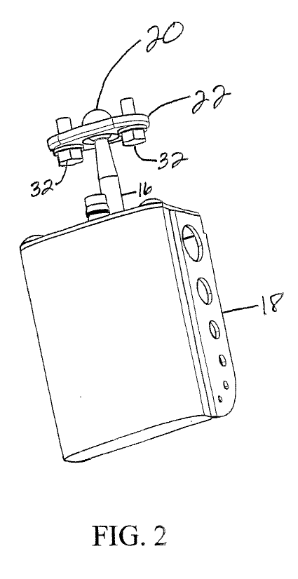

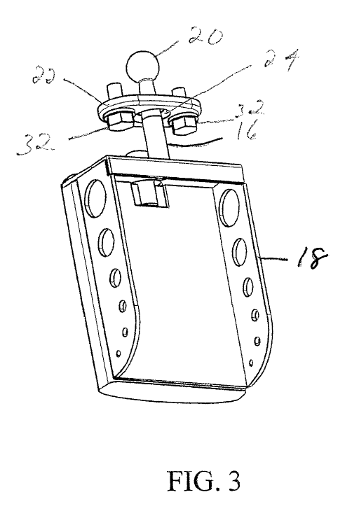

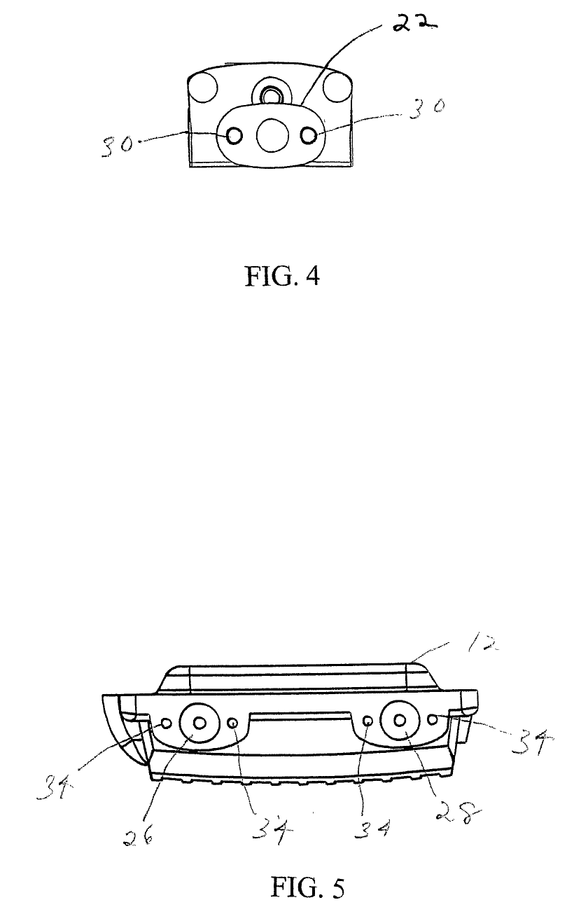

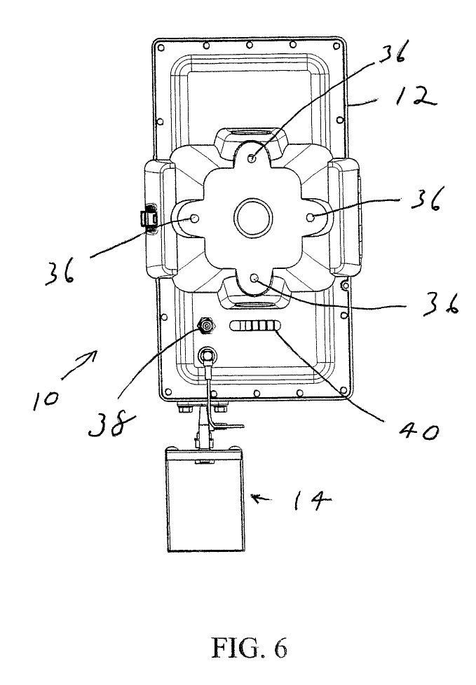

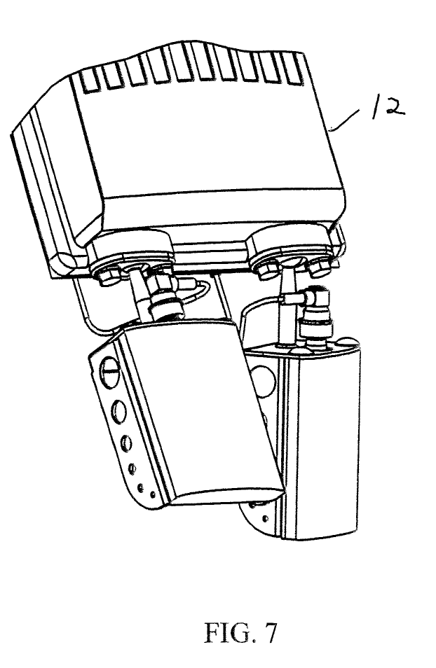

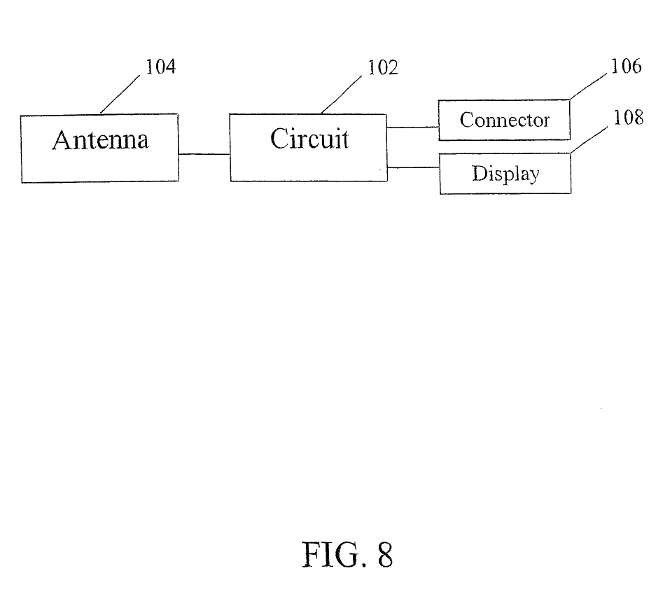

Referring to FIG. 1-7, a wireless encoder 10 has a housing 12 and antenna assembly 14. Antenna assembly 14 has a circular member 16 with one end attached to antenna 18. The other end of member 16 has a ball 20. Plate 22 has a center aperture 24 that is sized so that plate 22 can freely slide along member 16 but aperture 24 is smaller than ball 20 so that plate 22 is captive on member 16 between antenna 18 and ball 20. Housing 12 has cavities 26 and 28 that are sized to accommodate ball 20. Cavities 26 and 28 have a conical shape. Plate 22 has apertures 30 sized so that bolts 32 can be positioned in apertures 30 and screwed into threaded apertures 34 in housing 12. If bolts 32 are partially screwed into apertures 34, then the entire antenna assembly 14 can be moved by an installer to position antenna 18 in a desired positioned. Once antenna 18 is in a desired positioned, bolts 32 are tightened to secure ball 20 between the inside wall of cavity 26 and plate 22. The conical shape of cavity 26 provides the locking action. However, other shapes such as sphere could be used. FIG. 7 shows two antenna assemblies 14 connected to housing and positioned in different positions, thereby exhibiting the flexibility of the present invention to allow alignment of antennas 18 in an advantageous position for receiving signals of maximum strength. Housing 12 has a plurality of holes 36 for screws, bolts and the like to mount housing 12 to a pole, building, or other structure. FIG. 8 shows one embodiment of a schematic block diagram of the present invention. Circuit 102 is connected to antenna 104 to provide an output signal indicative of the strength of the signal received by antenna 104. The output from circuit 102 is connected to connector 106 and display 108. The signal provided by circuit 102 to connector 106 can be a voltage proportional to the strength of the signal received by wireless encoder 10. Display 108 can be a plurality of light emitting diodes or the like to provide an indication of the strength of the signal received by wireless encoder 10. FIG. 6 shows the location of electrical connector 38 and light emitting diodes 40 on housing 12 to provide an indicative of the strength of the signal received by wireless encoder 10. Accordingly, an installer can an adjust the position of antenna assembly 14 until the maximum strength signal is received by either connecting a voltmeter to electrical connector 38 or observing light emitting diodes 40 and then tighten bolts 32 to lock antenna assembly 14 in position.

It is to be understood that variations and modifications of the present invention can be made without departing from the scope of the invention. It is also to be understood that the scope of the invention is not to be interpreted as limited to the specific embodiments disclosed herein, but only in accordance with the appended claims when read in light of the foregoing disclosure.

What is claimed is:

1. A device for performing one of the functions from the group of functions of wireless transmission of a signal and wireless reception of a signal, said device comprising: a housing having a cavity on the outside surface of said housing; and an antenna assembly comprising an antenna mounted on a member, said member having a ball at one end that mates with said cavity, said member having a plate having an aperture sized so that it can be moved along said member and attached to said housing so that said antenna can be moved in three dimensions and then fixedly secured in said cavity by said plate.

2. A device as recited in claim 1, wherein said cavity has a conical shape.

3. A device as recited in claim 2 wherein said plate is adapted to provide varying degrees of tension on said ball.

4. A device as recited in claim 2 further comprising a circuit located in said housing and connected to said antenna for indicating the strength of a signal received by said antenna.

5. A device as recited in claim 4 further comprising a display located in said housing and connected to said circuit for displaying the strength of a signal received by said antenna, said display being positioned so that when a user is moving said antenna before said ball is fixedly secured in said aperture by said plate a user can view said display.

6. A device as recited in claim 5 wherein said display comprises light emitting diodes.

7. A device as recited in claim 4 further comprising a connector located on the outside of said housing and connected to said circuit for providing a voltage indicative of the strength of a signal received by said antenna.

8. A device as recited in claim 1 wherein said housing comprises a second cavity on the outside of said housing and a second antenna assembly comprising an antenna mounted on a member, said member having a ball at one end that mates with said cavity, said member having a plate having an aperture sized so that it can be moved along said member and attached to said housing so that said antenna can be moved in three dimensions and then fixedly secured in said cavity by said plate.
